(19) United States
(12) Patent Application Publication
(10) Pub. No.: US 2009/0167397 A1
(43) Pub. Date: Jul. 2, 2009

(54) Delay device for adjusting phase SMIA standard

(76) Inventors: Ching Yen Chang, Hsinchu City (TW); Wen-Bin Wang, Shengang Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/232,935

(22) Filed: Sep. 26, 2008

(30) Foreign Application Priority Data
Dec. 26, 2007 (TW) 96150276

(51) Int. Cl. H03K 5/13

(52) U.S. Cl. 327/233

(57) ABSTRACT

A delay device for adjusting phase under a SMIA (Standard Mobile Imaging Architecture) standard is provided. More particularly, the delay device is used to adjust a phase of a clock signal, which carries data, under the SMIA standard. The delay device includes plural delay cells, which are disposed on a circuit board by means of APR (Automated Placement and Routing) method, and one or more delay multiplexers (MUX) connected with the delay cells. Through selective pins controlling the route selection in the delay multiplexer, the delay device can produce plural delay times to adjust the phase relationship between data and clock, as supposed to using PLL.

### BACKGROUND OF THE INVENTION

1. Field of the Invention

The present invention is related to a delay device used for adjusting phase under a SMIA (Standard Mobile Imaging Architecture) standard, and more particularly to a delay device which has plural delay cells mounted in the image processing chip and a multiplexer used for selection so as to accurately lock the phase.

2. Description of Related Art

Owing to the development of mobile phone or other portable devices with photographing function, a SMIA (Standard Mobile Imaging Architecture) has used to regulate the image transmission of mobile device. The SMIA standard is an image processing architecture special for the mobile device, for obtaining a better processing efficiency between the SMIA-compliant sensor and the SMIA-compliant host. The SMIA standard regulates the housing, mechanical interconnection, functionality, register set and interface.

The SMIA standard defines two transmission modes: CLASS0 (as shown in FIG. 1) and CLASS1 (as shown in FIG. 2), wherein CLASS0 utilizes a data transmission rate under 208 Mbit/s, and CLASS1 utilizes a data transmission rate between 208 Mbit/s and 650 Mbit/s.

In CLASS1 transmission mode, data signal carries serial data. When data toggles, strobe signal does not toggle, and on the contrary, when data does not toggle, strobe signal toggles, so that only one of data and strobe toggles during transmission. As shown in FIG. 2, the original clock is displayed as TxClk. When the clock of data changes, the clock of strobe remains unchanged, so that the variations are alternated, and the operation result of data XOR strobe is working clock, shown as the last line of FIG. 2.

When data state doesn't change, the state of strobe signal line is switched. The receiver may operate “exclusive OR” on data and strobe for recovering the clock. Then, utilizing the rising edge and falling edge of this signal, the data is sampled. This sampling method is a DDR (Double Data Rate) method. Thus, when using CLASS1 transmission mode, it does not need to transmit continuous clock signal, and the frequency on the bus is only half. Therefore, it is easy to realize I/O cell and the electromagnetic interfering (EMI) thereof is also less than the CLASS0 transmission mode.

When CLASS1 transmission mode is operated under 650 Mbit/s, since each data is only about 1.67 ns and the sampling rate is DDR, for satisfying setup/hold time, the data and the internal clock after “exclusive OR” operation must have a stable phase relationship. Thus, the general method is to use PLL (phase-locked loop) to accurately control the phase difference for satisfying setup/hold time. And, it is easier to avoid influences of process shift, temperature and voltage in this method.

Please refer to FIG. 3, which is a clock diagram showing the setup/hold time in the prior art, wherein the data is carried by the rising edge of the clock. Since clock is very fast, the PLL used to control the setup/hold time in the prior art locks the data within about 1.67 ns. Because the phase difference of output edge is adjustable when the PLL feedback loop is accessible from the outside, the data in FIG. 3 can be kept at the unchanged portion around the rising edge, such as the setup portion data 301 and the hold portion data 302, which means the PLL locks the data at the rising edge or other suitable locations of the clock.

Please further refer to FIG. 4, which shows the frame architecture under SMIA standard in the prior art. When transmitting image between mobile devices, the SMIA standard is obeyed. The SMIA defines eleven image data formats, wherein synchronization code includes frame start bit code, such as SOF (Start of Frame, also known as frame start synchronization code), frame end bit code, such as EOF (End of Frame, also known as frame end synchronization code), line start code in image pixel array, such as SOL (Start of Line, also known as line start synchronization code), and line end code, such as EOL (End of Line, also known as line end synchronization code). Each synchronization code can be referenced to Table 1, which regulates SOL, EOL, SOF, EOF and logical channel.

| Synchronization code | Value |
|---|---|
| SOL | FF_{H}00_{H}00_{H}X0_{H} (X is logical channel) |
| EOL | FF_{H}00_{H}00_{H}X1_{H} |
| SOF | FF_{H}00_{H}00_{H}X2_{H} |
| EOF | FF_{H}00_{H}00_{H}X3_{H} |
| Logical channel | FF_{H}00_{H}00_{H}0X_{H} [symbol] FF_{H}00_{H}00_{H}7X_{H} |

Take Video Graphic Array (VGA) image shown in FIG. 4 as example. The data area shown in FIG. 4 is the image data defined between EOF and SOF (in VGA format, 480 lines from 1^{st} line to 480^{th} line), and also, a frame blanking period is defined outside the frame and a line blanking is defined between EOL and SOL. Conventionally, when transmitting this image data, PLL is utilized to lock the data at a proper phase position. If data is positioned in the frame blanking period or the line blanking, the clock signal will be gated or the transmission of clock signal will be stopped. But, if the data is transmitted again, it will need time to initiate PLL, and even when the PLL is initiated, it still has to switch from unlock state to lock state and consumes the so-called lock time. Then, if the clock is still gated, PLL will again have to take time to recover to the lock state. Which would increases the cost of chip.

### SUMMARY OF THE INVENTION

The object of the present invention is to provide a subLDVS (Sub Low-Voltage Differential Signaling) receiver under SMIA standard without using PPL, wherein delay multiplexer is used to adjust the phase relationship between data and clock, so that not only the cost is reduced, the lock time or other clock signals used for operating PLL can also be omitted.

The present invention provides a delay device for adjusting phase under a SMIA (Standard Mobile Imaging Architecture) standard including plural delay cells mounted on a circuit board, each of which having a delay amount, and one or more delay multiplexers electrically connected to the delay cells, wherein through selective pins controlling a route selection in the delay multiplexer, plural delay times can be produced.

Particularly, the delay device is mounted in a subLVDS (Sub Low-Voltage Differential Signaling) receiver for producing phase shift of the clock signal, thereby adjusting the phase relationship between data and clock.

### BRIEF DESCRIPTION OF THE DRAWINGS

The foregoing aspects and many of the attendant advantages of this application will be more readily appreciated as the same becomes better understood by reference to the following detailed description, when taken in conjunction with the accompanying drawings, wherein:

FIG. 1 shows data and clock of CLASS0 transmission mode under SMIA standard in the prior art;

FIG. 2 shows data and clock of CLASS1 transmission mode under SMIA standard in the prior art;

FIG. 3 shows the clock diagram of setup/hold time in the prior art;

FIG. 4 shows the frame architecture of Video Graphic Array (VGA) image under SMIA standard in the prior art;

FIG. 5 is a schematic view showing a delay device for generating clock shift according to the present invention;

FIG. 6 is a schematic view showing the delay device for adjusting phase under SMIA standard in an embodiment according to the present invention; and

FIG. 7 is a schematic view showing the delay device for adjusting phase under SMIA standard in an embodiment according to the present invention.

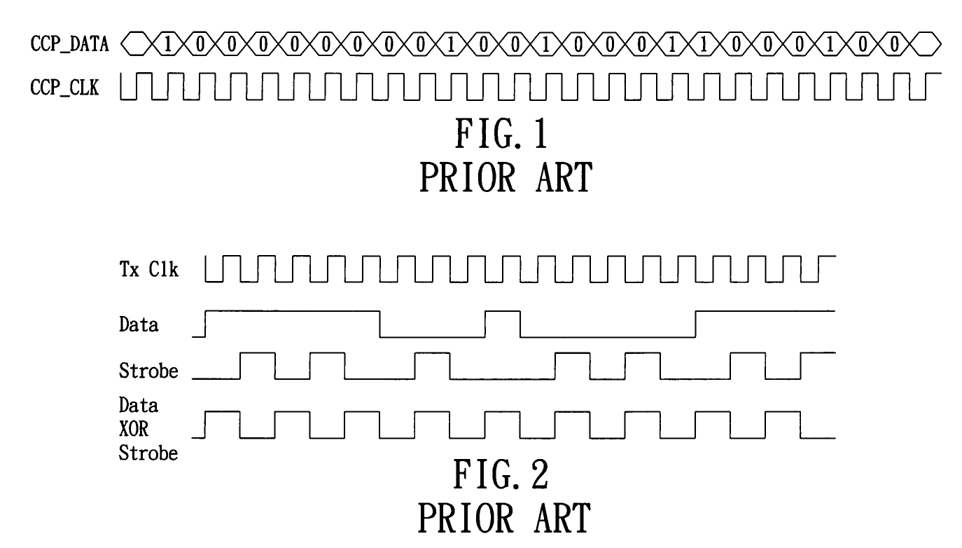

### DETAILED DESCRIPTION OF PREFERRED EMBODIMENTS

The present invention provides a subLVDS (Sub Low-Voltage Differential Signaling) receiver which can achieve the SMIA (Standard Mobile Imaging Architecture) standard without using PLL (Phase-Locked Loop). The subLVDS utilizes layout to achieve balance and utilizes delay MUX (multiplexer) to adjust the phase relationship between data and clock, so as to replace the use of PLL.

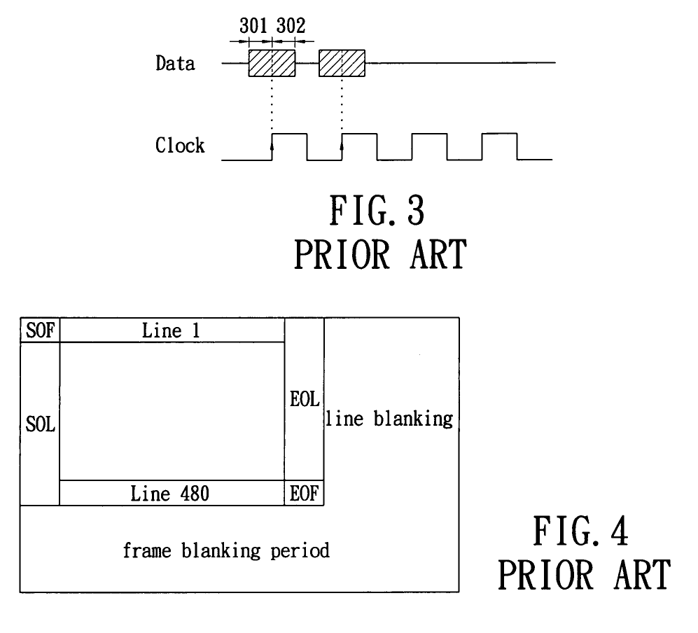

For stable transmission of data under SMIA standard at high speed, it has to adjust the data, such as images regulated by SOF and EOF or data in other formats, in an extremely short time so as to lock the data at a specific clock, just as the clock diagram of setup/hold time shown in FIG. 3. In this embodiment, since the data has to be locked at the rising edge of the clock, a stable phase must be maintained for the setup/hold time around the rising edge.

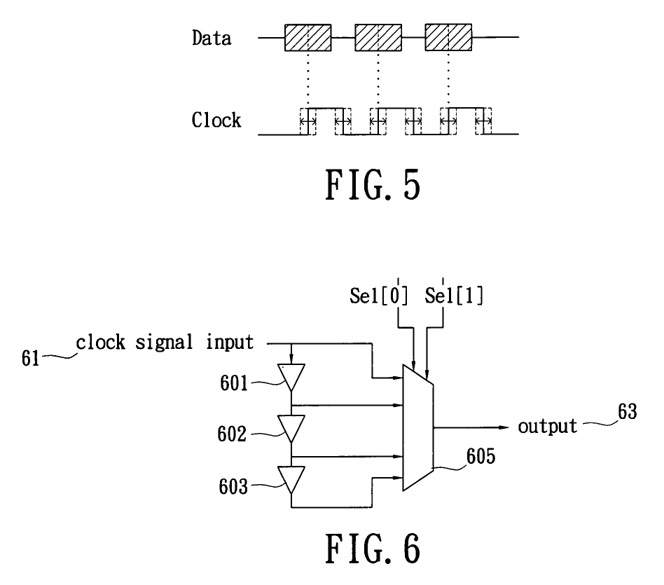

In a preferred embodiment, the delay MUX described above can be constituted by plural delay cells distributed on the circuit board. Especially in IC design, such as VLSI (Very Large Scale Integrated) circuits design, through assistance from APR (automated placement and routing) software, elements, such as delay cells, logical units (such as AND gate, OR gate), and transistors, can be properly distributed in a limited space. Then, through software simulation or hardware test, the actual delay amount between delay cells distributed over the circuit board can be measured. As shown in FIG. 5, which is a schematic view showing the relationship between data and clock, the phase shift of the clock signal can be adjusted through combination of plural delay cells in different quantity or with different delay amounts, especially for adjusting the location of the rising edge of the clock signal, so that a stable clock signal capable of carrying the data can be produced.

According to the actual demands of phase delay, the delay cells produced by means of ARP method described above can produce a needed delay amount through a selection of the multiplexer. FIG. 6, which is a schematic view showing the delay device used for adjusting phase, shows three delay cells 601, 602, 603, which are electrically connected. It should be noted, in practice, these delay cells might be distributed over the circuit board. While designing, according to the phase of the clock signal needed to be delayed, selective pins Sels (including Se[0] and Se[1]) are utilized to control the route of the delay multiplexer 605, so as to obtain the delay amount needed for the phase. As shown, clock signal (61) is inputted to this delay device, and after selection, delay multiplexer 605 decides the number of delay cells to be passed, so as to obtain a proper delay amount and output the needed clock signal (63).

For satisfying the request of setup/hold time, a combination of plural delay devices as shown in FIG. 6 also can be used to adjust the phase relationship of data and clock, thereby allowing a gated clock under the SMIA standard. Therefore, when the clock frequently stops and starts, the delay device doesn't need any lock time and is still able to immediately have a quick response at the output terminal of delay multiplexer 605 by using the phase delay.

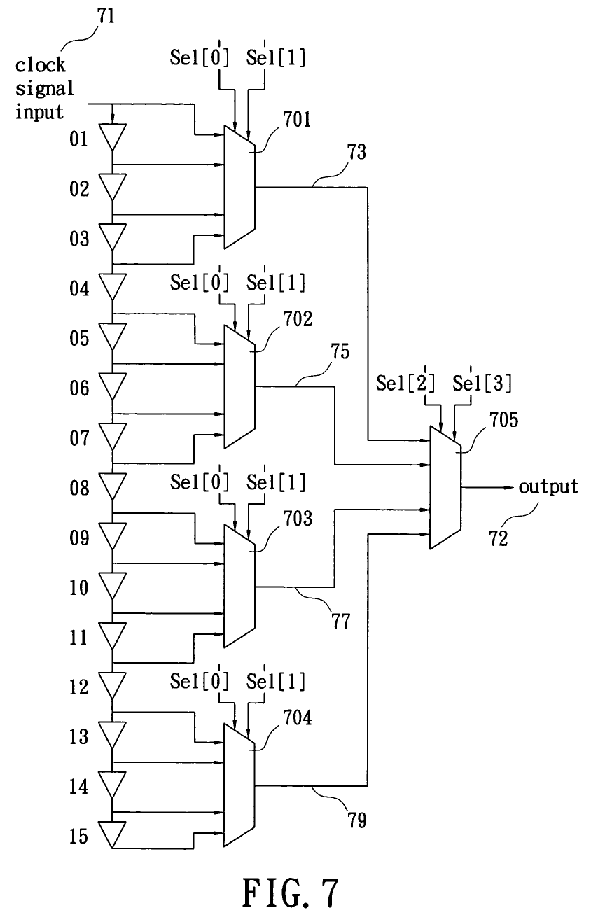

Please refer to FIG. 7, which is a schematic view showing a delay apparatus which combines plural delay devices for adjusting phase, clock signal input (71) is inputted into a delay apparatus, which is constituted by plural delay cells 1, 2, 3, 4, 5, 6, 7, 8, 9, 10, 11, 12, 13, 14, 15 and plural delay multiplexers 701, 702, 703, 704, 705, and the delay cells are electrically connected with each other. Here, the delay cells are connected in serial. Each delay cell has a specific delay amount, and the magnitude of the delay amount is decided by the position of the delay cell on the circuit board and the distance between each other. Besides, each delay multiplexer is electrically connected to one or more delay cells, which depends on the real situation and thus is not limited. Therefore, through the selection signals produced by selective pins Sel[0], Sel[1], Sel[2] and Sel[3] of each delay multiplexer, proper delay outputs can be generated, so as to output a delay clock signal (72).

The embodiments of the present invention are mainly used under the SMIA standard for adjusting phase of clock signal during data transmission, wherein through utilizing plural delay cells disposed in the image processing chip and the selection by the delay multiplexer, the phase can be locked accurately.

Take FIG. 7 as example, which is supposed that each delay cell can have a delay of 100 ps (picosecond). First delay multiplexer 701 is electrically connected to delay cells 1, 2, 3, and controls by selective pins Sel[0] and Sel[1], the inputted clock signal can have a 0 to 300 ps delay by first delay multiplexer 701. Then, output delay amount (73) is further inputted to fifth delay multiplexer 705. Identically, second delay multiplexer 702 is electrically connected to delay cells 4, 5, 6, 7, and controls by selective pins Sel[0] and Sel[1] of this multiplexer, the inputted clock signal can have a 0 to 400 ps delay by second delay multiplexer 702. Then, output delay amount (75) is further inputted to fifth delay multiplexer 705. Therefore, through cooperating with the output of first delay multiplexer 701, it can have a 0 to 700 ps delay amount.

Moreover, third delay multiplexer 703 is electrically connected to delay cells 8, 9, 10, 11, and controls by selective pins Sel[0] and Sel[1] of this multiplexer, the inputted clock signal can have a 0 to 400 ps delay by third delay multiplexer 703. Then, output delay amount (77) is further inputted to fifth delay multiplexer 705. Therefore, through cooperating with the outputs of first delay multiplexer 701 and second delay multiplexer 702, it can have a 0 to 1100 ps delay amount. Furthermore, fourth delay multiplexer 704 is electrically connected to delay cells 12, 13, 14, 15, and controls by selective pins Sel[0] and Sel[1], the inputted clock signal can have a 0 to 400 ps delay by fourth delay multiplexer 704. Then, output delay amount (79) is further inputted to fifth delay multiplexer 705. Therefore, through cooperating with the outputs of first delay multiplexer 701, second delay multiplexer 702 and third delay multiplexer 703, it can have a 0 to 1500 ps delay amount.

Finally, the output of each delay multiplexer is inputted to an integration delay multiplexer, which is a multiplexer used for integrating all multiplexers, such as fifth multiplexer 705, which is electrically connected to the delay multiplexers 701, 702, 703, 704. Then, controlled by selective pins Sel[2] and Sel[3] of fifth delay multiplexer 705, the route can be adjusted, so that plural kinds of delay times (72) can be outputted. Consequently, through the integration of plural delay times inputted by plural delay multiplexers, a phase shift of the received clock signal can be produced under the SMIA standard, thereby the phase relationship between data and clock can be adjusted. The integrated delay time produced by the combination above is 0 to 1500 ps.

In addition, this combination can still continue to couple with other delay device, delay cell or delay multiplexer, so as to produce more flexible delay amount for complying with more demands.

In the aforesaid, the present invention discloses a delay device for adjusting phase under the SMIA standard so as to realize subLVDS receiver without using PLL (phase locked loop), wherein the delay multiplexer is used to adjust the phase relationship between data and clock, so that not only the cost can be reduced, but the lock time used for operating PLL can also be omitted.

It is to be understood, however, that even though numerous characteristics and advantages of the present application have been set forth in the foregoing description, together with details of the structure and function of the application, the disclosure is illustrative only, and changes may be made in detail, especially in matters of shape, size, and arrangement of parts within the principles of the application to the full extent indicated by the broad general meaning of the terms in which the appended claims are expressed.

What is claimed is:

1. A delay device for adjusting phase under a SMIA (Standard Mobile Imaging Architecture) standard, comprising:
plural delay cells, mounted on a circuit board, each of which having a delay amount; and
at least a delay multiplexer, electrically connected to the delay cells and having plural selective pins for producing plural delay times,
wherein the delay device is mounted in a subLVDS (Sub Low-Voltage Differential Signaling) receiver under SMIA standard for producing a phase shift of a clock signal received under the SMIA standard, so as to adjust a phase relationship between data and clock.

2. The delay device as claimed in claim 1, wherein the phase shift is used to adjust a stable phase within a setup/hold time around a rising edge of the clock signal.

3. The delay device as claimed in claim 1, wherein the delay cells are mounted on the circuit board through an APR (automated placement and routing) method.

4. The delay device as claimed in claim 1, wherein the data are files transmitted under SMIA standard.

5. The delay device as claimed in claim 1, wherein the delay multiplexer is further electrically connected to another delay multiplexer for producing more kinds of delay times.

6. A delay apparatus for adjusting phase under a SMIA (Standard Mobile Imaging Architecture) standard, comprising:
plural delay cells, mounted on a circuit board and electrically connected with each other, each of which having a delay amount;
plural delay multiplexers, each of which being electrically connected to at least one of the delay cells and having plural selective pins for producing a delay time; and
an integration delay multiplexer, electrically connected to the delay multiplexers, wherein through the selective pins controlling routes in the integration delay multiplexer, the inputted delay times from the delay multiplexers are integrated into an integration delay time,
wherein the delay device is mounted in a subLVDS (Sub Low-Voltage Differential Signaling) receiver under SMIA standard for producing a phase shift of a clock signal received under the SMIA standard, so as to adjust a phase relationship between data and clock.

7. The delay apparatus as claimed in claim 6, wherein the phase shift is used to adjust a stable phase within a setup/hold time around a rising edge of the clock signal.

8. The delay apparatus as claimed in claim 6, wherein the delay cells are mounted on the circuit board through an APR (automated placement and routing) method.

9. The delay apparatus as claimed in claim 6, wherein the data is files transmitted under SMIA standard.
